(19) United States
(12) Patent Application Publication
(10) Pub. No.: US 2023/0162633 A1
(43) Pub. Date: May 25, 2023

(54) POV DISPLAY DEVICE AND CONTROL METHOD THEREFOR

(71) Applicant: LG ELECTRONICS INC., Seoul (KR)

(72) Inventors: Kyungho LEE, Seoul (KR); Jaewoon LEE, Seoul (KR); Jeongin CHEON, Seoul (KR)

(73) Assignee: LG ELECTRONICS INC., Seoul (KR)

(21) Appl. No.: 17/916,977

(22) PCT Filed: Apr. 24, 2020
(86) PCT No.: PCT/KR2020/005471

§ 371 Date: Oct. 4, 2022

(51) Int. Cl. G09G 3/00

(52) U.S. Cl. CPC G09G 3/001; G09G 2320/02; G09G 2340/14

(57) ABSTRACT

The present invention relates to a POV display device using a light-emitting element, comprising: a fixed module including a motor; a rotary module located above the fixed module and rotated by means of the motor; at least one panel coupled to the rotary module; a plurality of light sources which are arranged on the panel and which have a plurality of pixels; a light source module including a light-emitting element array in which the plurality of light sources are arranged in the longitudinal direction thereof; and a controller for generating, between a first main frame and a second main frame, at least one subframe formed by means of the panel, wherein the first main frame can temporally precede the second main frame.

### TECHNICAL FIELD

The present disclosure is applicable to a display device-related technical field, and relates, for example, to a POV display device using light emitting diodes (LED), which are semiconductor light emitting elements.

### BACKGROUND ART

In a field of a display technology, display devices having excellent characteristics such as thinness, flexibility, and the like have been developed. On the other hand, currently commercialized major displays are represented by a LCD (liquid crystal display) and an OLED (organic light emitting diode).

Recently, there is a POV display device that may reproduce various characters and graphics as well as moving images using an afterimage effect of a human by rotating a light emitting module in which light emitting elements are one-dimensionally arranged, and at the same time, driving the light emitting module at a high speed based on an angle.

In general, when continuously observing 24 or more still images for each second, a viewer recognizes the still images as the moving image. A conventional image display device, such as a CRT, the LCD, or a PDP, displays still images of 30 to 60 frames for each second, so that the viewer may recognize the still images as the moving image. In this regard, when continuously observing more still images for each second, the viewer may feel smoother images. As the number of still images displayed for each second decreases, it becomes difficult to smoothly display the images.

In a case of rotation type-display, afterimages of a preceding frame and a following frame appear to be in contact with each other resulted from rotation of a panel, and accordingly, a tearing phenomenon in which a screen of the contact portion of both frames is torn in a process of frame conversion occurs.

Therefore, a method for solving such tearing phenomenon of the POV display device is required.

### DISCLOSURE

### Technical Problem

The present disclosure is to provide a POV (Persistence of Vision) display device using light emitting elements that may solve a tearing phenomenon resulted from image output of the POV display device.

### Technical Solutions

As a first aspect for achieving the above object, the present disclosure provides a persistence of vision display device using light emitting elements including a fixed module including a motor, a rotatable module positioned on the fixed module and rotated by the motor, at least one panel coupled to the rotatable module, a plurality of light sources arranged on the panel and constituting a plurality of pixels, a light source module including a light emitting element array having the plurality of light sources arranged in a longitudinal direction, and a controller that generates at least one sub-frame at a location between a first main frame and a second main frame formed by the panel, wherein the first main frame precedes the second main frame in time.

In addition, the controller may multiply the first main frame and the second main frame by weights, respectively, during each image scanning duration, and generate the at least one sub-frame by combining the first main frame and the second main frame respectively multiplied by the weights with each other.

In addition, the controller may detect a difference between the first main frame and the second main frame, select linear weights as the weights when the difference is equal to or greater than a preset threshold value, and select non-linear weights as the weights when the difference is smaller than the preset threshold value.

In addition, the controller may increase the weights in a portion where an amount of change between the first main frame and the second main frame is small when the non-linear weights are selected as the weights.

In addition, the controller may, when the panel includes a plurality of panels, divide an image scanning area into areas for the respective panels, and apply the weights to the areas.

As a first aspect for achieving the above object, the present disclosure provides a method for controlling a POV display device including inputting image data of a first main frame and a second main frame, detecting weights, applying the weights to the first main frame and the second main frame, respectively, forming a sub-frame by combining the first main frame and the second main frame applied with the weights to each other, and outputting synthesized image data.

In addition, the detecting of the weights may include detecting a difference between the first main frame and the second main frame, selecting linear weights as the weights when the difference is equal to or greater than a preset threshold value, and selecting non-linear weights as the weights when the difference is smaller than the preset threshold value.

In addition, the selecting of the non-linear weights as the weights may further include pre-processing images of the first main frame and the second main frame, and detecting the weights of the frames based on analysis of the image.

In addition, the method may further include, before the inputting of the image data of the first main frame and the second main frame, dividing an image scanning area into areas for respective panels when there are the plurality of panels.

### Advantageous Effects

According to one embodiment of the present disclosure, the problem as described above may be solved.

That is, the occurrence of the tearing in the image of the POV display device may be solved.

Furthermore, in the present disclosure, there are additional technical effects not mentioned here, and those skilled in the art are able to understand such effects through the entirety of the specification and the drawings.

### DESCRIPTION OF DRAWINGS

FIG. 1 is a perspective view showing a POV (Persistence Of Visual) display device according to an embodiment of the present disclosure.

FIG. 2 is a diagram showing a conventional image output scheme.

FIG. 3 is a diagram showing frames based on a conventional image output scheme.

FIG. 4 is a block diagram of a POV display device according to an embodiment of the present disclosure.

FIG. 5 is a diagram showing an image output scheme according to an embodiment of the present disclosure.

FIG. 6 is a diagram showing frames based on an image output scheme according to an embodiment of the present disclosure.

FIG. 7 is a diagram showing a combining scheme in a case in which weights are linearly applied according to an embodiment of the present disclosure.

FIG. 8 is a diagram showing a combining scheme in a case in which weights are linearly applied according to an embodiment of the present disclosure.

FIG. 9 is a diagram showing a combining scheme in a case in which weights are non-linearly applied according to an embodiment of the present disclosure.

FIG. 10 is a flowchart of forming a sub-frame according to an embodiment of the present disclosure.

FIG. 11 is a diagram more specifically showing a flowchart of forming a sub-frame according to an embodiment of the present disclosure.

### BEST MODE

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting element mentioned in this specification is a concept including an LED, a micro LED, and the like, and may be used interchangeably therewith.

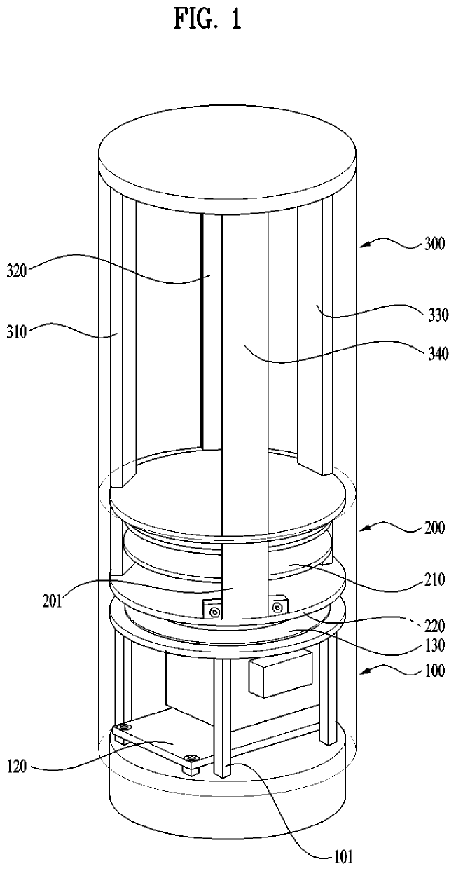

FIG. 1 is a perspective view showing a POV (Persistence of Visual) display device according to an embodiment of the present disclosure.

FIG. 1 shows a POV display device in which each light emitting element array (not shown) is disposed on each of fan type-panels 310, 320, 330, and 340 in a longitudinal direction of each panel.

Although FIG. 1 shows a cylinder type-POV display device, the present disclosure is also applicable to a fan type-POP display device.

Such POV display device may largely include a fixed module 100 including a motor 110, a rotatable module 200 positioned on this fixed module 100 and rotated by the motor 110, and a light source module 300 that is coupled to the rotatable module 200, includes the light emitting element arrays, and displays an afterimage by the rotation so as to implement a display.

In this regard, the light source module 300 may include the one or more bar-shaped panels 310, 320, 330, and 340 radially disposed from a central point of rotation. However, this is an example, and the light source module 300 may include one or more panels.

The light source module 300 may include the light emitting element arrays arranged on the panels 310, 320, 330, and 340 in the longitudinal direction, respectively.

Each of the panels 310, 320, 330, and 340 constituting the light source module 300 may form a printed circuit board (PCB). That is, each of the panels 310, 320, 330, and 340 may have a function of the printed circuit board. In each of such panels, each of the light emitting element arrays may implement individual unit pixels and may be disposed in the longitudinal direction of each panel.

The panels 310, 320, 330, and 340 respectively equipped with such light emitting element arrays may implement the display while rotating using the afterimage. The implementation of the afterimage display will be described in detail below.

As such, the light source module 300 may be composed of the panels 310, 320, 330, and 340 on which the light emitting element arrays are respectively arranged.

That is, multiple light emitting elements (not shown) may be arranged in one direction on each of the panels 310, 320, 330, and 340 to constitute pixels so as to constitute each of the light emitting element arrays. In this regard, a light emitting diode (LED) may be used as the light emitting element.

On each of the panels 310, 320, 330, and 340, each of the light emitting element arrays on which the light emitting elements are arranged to form individual pixels in one direction and are linearly installed may be disposed.

As mentioned above, the light source module 300 may be composed of the multiple panels 310, 320, 330, and 340, but may also be implemented with a single panel including the light emitting element arrays. However, when the light source module 300 is implemented with the multiple panels as in the example in FIG. 1, because the multiple panels may implement one frame image in a divided manner, the light source module 300 may rotate at a lower rotation speed than when implementing the image of the same frame.

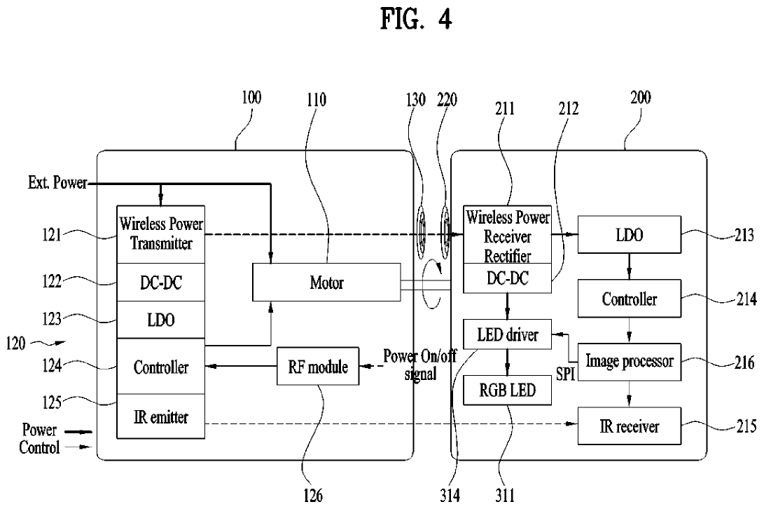

In one example, drivers 314 (see FIG. 4) for driving the light emitting elements may be installed on a rear surface of each of the panels 310, 320, 330, and 340 constituting the light source module.

As such, the drivers 314 are installed on the rear surface of each of the panels 310, 320, 330, and 340, so that a light emitting surface of each panel may not be disturbed, an effect on lighting of light sources (the light emitting elements) caused by interference or the like may be minimized, and the panels 310, 320, 330, and 340 may be constructed with minimal areas. Such panels 310, 320, 330, and 340 with the small areas may improve transparency of the display.

In one example, a front surface of each of the panels 310, 320, 330, and 340 on which each light emitting element array is installed may be treated with a dark color (for example, black) so as to improve a contrast ratio, a color, and the like of the display, thereby maximizing an effect of the light sources.

In one example, the fixed module 100 may form frame structures. That is, the fixed module 100 may include multiple frames 101 that are designed to be divided from each other and coupled with each other.

Such frame structures may provide a space in which the motor 110 may be installed, and may provide a space in which a power supply 120, an RF module 126 (see FIG. 4), and the like are installed.

In addition, a weight (not shown) may be installed in the fixed module 100 in order to reduce an effect of the high-speed rotation of the rotatable module 200.

Similarly, the rotatable module 200 may form frame structures. That is, the rotatable module 200 may include multiple frames 201 that are designed to be divided from each other and coupled with each other.

Such frame structures may provide a space in which a driving circuit 210 for driving the light emitting element arrays to implement the display is installed.

In this regard, a driving shaft of the motor 110 may be fixed with a shaft fixing module formed in a lower frame 201 of the rotatable module 200. As such, the driving shaft of the motor 110 and a center of rotation of the rotatable module 200 may be located on the same axis.

In addition, the light source module 300 may be fixedly installed on the frame structures.

In one example, power may be transferred between the fixed module 100 and the rotatable module 200 in a wireless power transfer scheme. To this end, a transfer coil 130 for transmitting wireless power may be installed at a top of the fixed module 100, and a receiving coil 220 located at a position facing the transfer coil 130 may be installed at a bottom of the rotatable module 200.

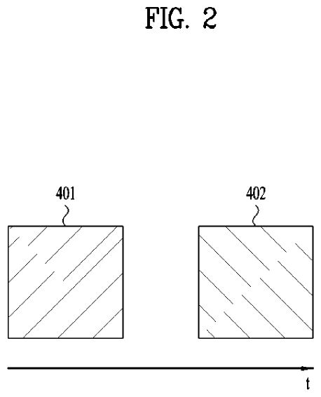

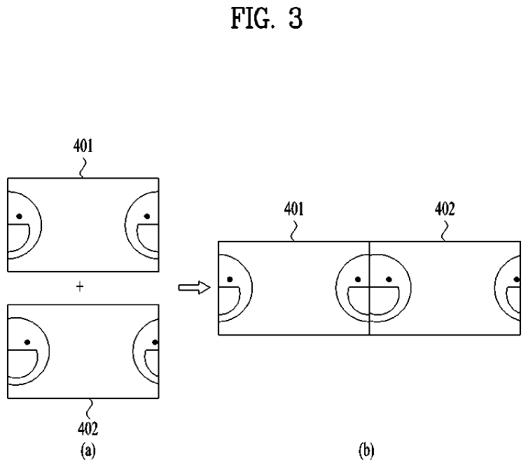

FIG. 2 is a diagram showing a conventional image output scheme, and FIG. 3 is a diagram showing frames based on a conventional image output scheme.

Conventionally, when converting frames, as shown in FIG. 2, a first main frame 401 is converted into a second main frame 402 without a separate sub-frame, so that a screen tearing phenomenon, that is, a tearing phenomenon occurred between the first main frame 401 and the second main frame 402 as shown in FIG. 3.

When such a tearing phenomenon occurs, there was a problem in that an image is displayed unnaturally because the image is not continuously and naturally converted.

FIG. 4 is a block diagram of a POV display device according to an embodiment of the present disclosure that has solved the above problem.

Hereinafter, a configuration for driving the POV display device will be briefly described with reference to FIG. 4. Such configuration may be equally applied to not only the cylinder type-POV display device shown in FIG. 1, but also the fan type-POV display device.

First, a driving circuit 120 may be installed in the fixed module 100. Such driving circuit 120 may include a power supply. The driving circuit 120 may include a wireless power transmitter 121, a DC-DC converter 122, and an LDO 123 for supplying individual voltages.

External power may be supplied to the driving circuit 120 and the motor 110.

In addition, the fixed module 100 may have an RF module 126, so that the display may be driven by a signal transmitted from the outside.

In one example, the fixed module 100 may have means for sensing the rotation of the rotatable module 200. An infrared ray may be used as such means for sensing the rotation. Accordingly, an IR emitter 125 may be installed in the fixed module 100, and an IR receiver 215 may be installed in the rotatable module 200 at a location corresponding to an infrared ray emitted from such IR emitter 125.

In addition, the fixed module 100 may include a controller 124 for controlling the driving circuit 120, the motor 110, the IR emitter 125, and the RF module 126.

In one example, the rotatable module 200 may include a wireless power receiver 211 for receiving a signal from the wireless power transmitter 121, a DC-DC converter 212, and an LDO 213 for supplying individual voltages.

The rotatable module 200 may have an image processor 216 that processes the image to be realized via the light emitting element arrays using RGB data of the displayed image. A signal processed by the image processor 216 may be transmitted to the driver 314 of the light source module 300 so as to realize the image.

In addition, in the rotatable module 200, a controller 214 for controlling the wireless power receiver 211, the DC-DC converter 212, the LDO 213, the IR receiver 215, and the image processor 216 may be installed.

Such image processor 216 may generate a signal for controlling light emission of the light sources of the light source module 300 based on image data to be output. In this regard, data for the light emission of the light source module 300 may be internal or external data.

The data stored internally (in the rotatable module) 200 may be image data stored in advance in a storage device, such as a memory (e.g., a SD card), mounted together in the image processor 216. The image processor 216 may generate the light emission control signal based on such internal data.

The image processor 216 may transmit, to the driver, a signal for controlling image data of a specific frame to be displayed on each light emitting element array after delay.

In addition, the image processor 216 may receive the image data from the fixed module 100. In this regard, the external data may be output via an optical data transmitting device with the same principle as a photo coupler, or a data transmitting device of an RF scheme such as Bluetooth or Wi-Fi.

In this regard, as mentioned above, the means for sensing the rotation of the rotatable module 200 may be disposed. That is, as means for recognizing a location (a speed) with respect to the rotation, such as an absolute location and a relative location with respect to the rotation, so as to output light source data suitable for each rotational position (speed) during the rotation of the rotatable module 200, the IR emitter 125 and the IR receiver 215 may be arranged. In one example, the same function may be implemented via an encoder, a resolver, and a Hall sensor.

In one example, data required to drive the display may optically transmit a signal at a low cost using the principle of the photo coupler. That is, when the light emitting elements and light receiving elements are positioned in the fixed module 100 and the rotatable module 200, the data may be received without interruption even when the rotatable module 200 rotates. In this regard, the IR emitter 125 and the IR receiver 215 described above may be used for such data transmission.

As described above, the power may be transferred between the fixed module 100 and the rotatable module 200 using the wireless power transfer (WPT).

The power may be supplied without a wire connection using a resonance shape of the wireless power transfer coil.

To this end, the wireless power transmitter 121 may convert the power into an RF signal of a specific frequency, and a magnetic field generated by a current flowing through the transfer coil 130 may generate an induced current in the receiving coil 220.

In this regard, a natural frequency of the coil and a transmission frequency at which actual energy is transmitted may be different from each other (a magnetic induction scheme).

In one example, resonant frequencies of the transfer coil 130 and the receiving coil 220 may be the same with each other (a self-resonant scheme).

The wireless power receiver 211 may convert the RF signal input from the receiving coil 220 into a direct current so as to transmit required power to a load.

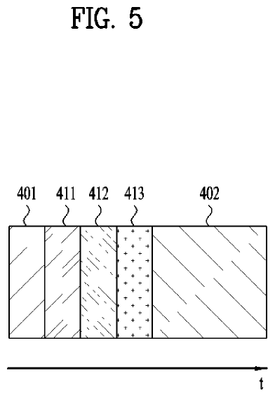

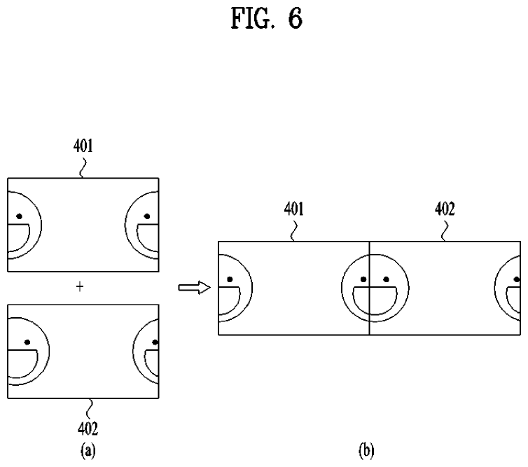

FIG. 5 is a diagram showing an image output scheme according to an embodiment of the present disclosure, and FIG. 6 is a diagram showing frames based on an image output scheme according to an embodiment of the present disclosure.

As shown in FIG. 5, the present disclosure may form and output sub-frames 411, 412, and 413 during the conversion from the first main frame 401 to the second main frame 402.

That is, the image signal processor 216 (see FIG. 4) may form the at least one sub-frame at a location between the first main frame 401 and the second main frame 402 formed by the panels 310, 320, 330, and 340.

In this regard, the first main frame 401 temporally precedes the second main frame 402.

In this case, as shown in FIG. 6, at a point at which the first main frame 401 and the second main frame 402 meet each other, the images may be continuously and naturally converted without the tearing phenomenon.

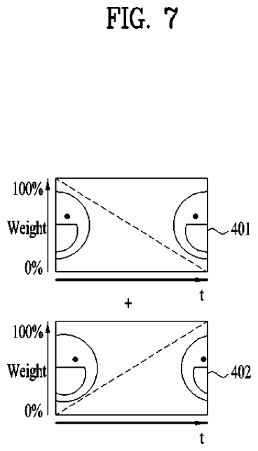

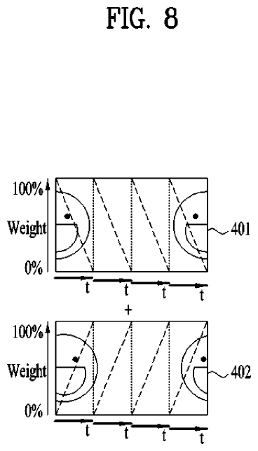

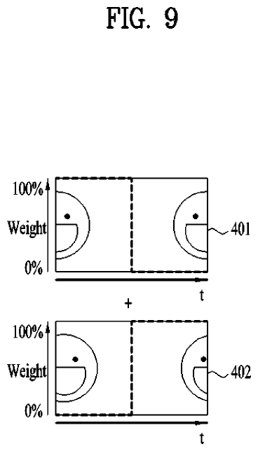

FIGS. 7 and 8 are diagrams showing a combining scheme in a case in which weights are linearly applied according to an embodiment of the present disclosure, and FIG. 9 is a diagram showing a combining scheme in a case in which weights are non-linearly applied according to an embodiment of the present disclosure.

As shown in FIGS. 7 to 9, the sub-frame may be formed by multiplying the first main frame 401 and the second main frame 402 by the weights, respectively, during each image scanning duration, and combining the first main frame 401 and the second main frame 402 to which the weights are applied to each other.

FIG. 7 is a diagram showing a scheme for combining the first main frame 401 and the second main frame 402 to each other by applying a linear algorithm in a case in which there is one panel.

FIG. 8 is a diagram illustrating a scheme of combining the first main frame 401 and the second main frame 402 to each other by applying the linear algorithm in a case in which there are two or more panels 310, 320, 330, and 340. In this case, after dividing an image scanning area of each frame into areas for respective panels, the respective divided areas of the frames are multiplied by the weights, respectively, and the frames are combined with each other in the same manner as in FIG. 7. Four panels 310, 320, 330, and 340 are shown in FIG. 1, but the number of panels is irrelevant as long as there are two or more panels when using the combining scheme in the case in which there are a plurality of panels in FIG. 8.

In this regard, the weight may be applied to the first main frame 401 while decreasing from 100% to 0%, and the weight may be applied to the second main frame 402 while increasing from 0% to 100%.

In this regard, in terms of the weights, linear weights may be selected when a difference between the first main frame 401 and the second main frame 402 is equal to or greater than a preset threshold value, and non-linear weights may be selected when the difference is smaller than the preset threshold value.

FIG. 9 is a diagram showing a scheme of combining the first main frame 401 and the second main frame 402 to each other by applying a non-linear algorithm in the case in which there is one panel. In this regard, the weight may be changed to become great, and be applied to a portion with a small amount of change between the first main frame 401 and the second main frame 402, such as a background or a still portion. When the non-linear algorithm is applied, a problem of sharpness deterioration by the image combination of the linear algorithm may be compensated.

When the non-linear weights are selected, the weight may be increased in the portion in which the amount of change between the first main frame 401 and the second main frame 402 is small.

When the non-linear weights are selected, the problem of the sharpness deterioration by the image combination may be compensated than in the case in which the linear weights are selected.

In addition, when there are the plurality of panels, the image signal processor 216 may divide the image scanning area into the areas for the respective panels, and apply the weight to each area.

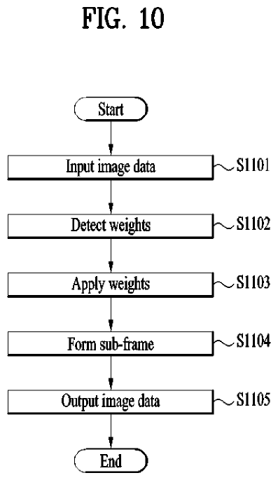

FIG. 10 is a flowchart of forming a sub-frame according to an embodiment of the present disclosure.

As shown in FIG. 10, first, the first and second main frames 401 and 402 are input (s1101), and the weights of the first and second main frames 401 and 402 are detected (s1102). The detected weights are applied to the first and second main frames 401 and 402, respectively, and the first and second main frames 401 and 402 are combined with each other (s1103) so as to form a first sub-frame 411 (s1104). The first sub-frame 411 thus formed may be output at the location between the first and second main frames 401 and 402

The weight may be applied to the first main frame 401 while decreasing from 100% to 0% and the weight may be applied to the second main frame 402 while increasing from 0% to 100% during each image scanning duration.

By repeating the processes from s1101 to s1105, n sub-frames may be formed.

The first sub-frame 411 temporally precedes second and third sub-frames 412 and 413, and the second sub-frame 412 temporally precedes the third sub-frame 413.

Although FIG. 5 shows the first, second, and third sub-frames 411, 412, and 413, the number of sub-frames is not limited thereto. The number of sub-frames may be equal to or greater than one.

In a following image, the second main frame 402 may become the first main frame 401, and a third main frame (not shown) may become the second main frame 402.

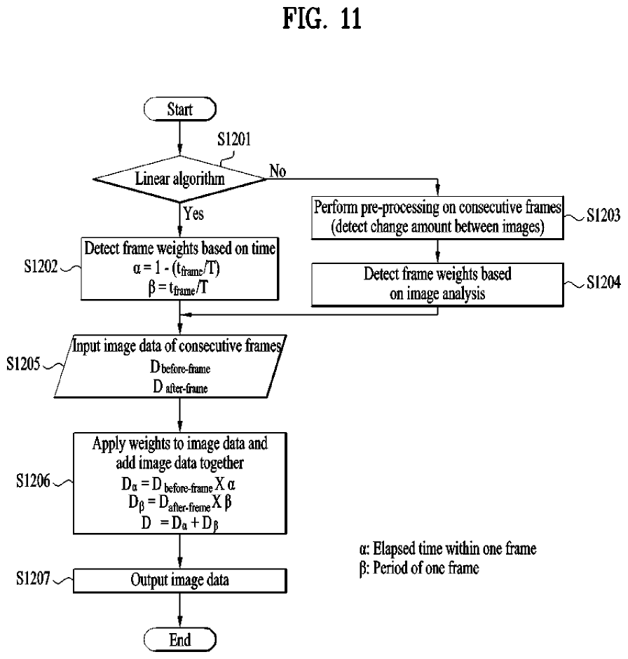

FIG. 11 is a diagram more specifically showing a flowchart of forming a sub-frame according to an embodiment of the present disclosure.

As shown in FIG. 11, first, the difference between the first main frame 401 and the second main frame 402 is detected, and whether to apply the linear algorithm is determined based on the detected difference value. Specifically, when the detected difference value is equal to or greater than the preset threshold value, the linear weights are applied as the weight, and when the detected difference value is smaller than the preset threshold value, the non-linear weights are applied as the weight (s1201).

When the linear weights are applied, an elapsed time within one frame is set to t_{frame}, a period of one frame is set to T, and values of α and β are detected based on Mathematical Equations 1 and 2 below (s1202).

α=1−(t_{frame}/T) [Mathematical Equation 1]

β=(t_{frame}/T) [Mathematical Equation 2]

In the present disclosure, there may be one or the plurality of panels. In this regard, the POV display device of the present disclosure is a display that outputs the image by the afterimage. The minimum required number of panels may be determined based on a rotation speed. As the number of panels increases, the rotation speed may be lowered.

When the non-linear weights are applied, images of the first main frame 401 and the second main frame are preprocessed (s1203), and the weights of the first and second main frames are detected based on such analysis (s1204).

D (before-frame) and D (after-frame) values that are respectively image data of the first main frame 401 and the second main frame 402 are input (s1205), and the detected weights are applied to such image data values and the image data values to which the weights are applied are added together Based on Mathematical Equations 3 to 5 below (s1206).

D_{α}=D_{before-frame}X_{α} [Mathematical Equation 3]

D_{β}=D_{after-frame}X_{β} [Mathematical Equation 4]

D=D_{α}+D_{β} [Mathematical Equation 5]

Here, D is image data of the first sub-frame 411 obtained by applying the weights to the image data of the first and second main frames 401 and 402 and then adding the image data to which the weights are applied together.

The synthesized image data is output (s1207).

The weight may be applied to the first main frame 401 while decreasing from 100% to 0% and the weight may be applied to the second main frame 402 while increasing from 0% to 100% during each image scanning duration.

By repeating the processes from s1201 to s1207, n sub-frames may be formed.

Although FIG. 5 shows the first, second, and third sub-frames 411, 412, and 413, the number of sub-frames is not limited thereto. The number of sub-frames may be equal to or greater than one.

In the following image, the second main frame 402 may become the first main frame 401, and the third main frame (not shown) may become the second main frame 402.

As such, in the present disclosure, the POV display device may solve the occurrence of the phenomenon in which the screen is torn in the process of the frame conversion, that is, the tearing phenomenon by synthetizing and outputting the sub-frame to which the weights of the first main frame 401 and the second main frame 402 based on the image scanning duration are applied between the first main frame 401 and the second main frame 402.

The above description is merely illustrative of the technical idea of the present disclosure. Those of ordinary skill in the art to which the present disclosure pertains will be able to make various modifications and variations without departing from the essential characteristics of the present disclosure.

Therefore, embodiments disclosed in the present disclosure are not intended to limit the technical idea of the present disclosure, but to describe, and the scope of the technical idea of the present disclosure is not limited by such embodiments.

The scope of protection of the present disclosure should be interpreted by the claims below, and all technical ideas within the scope equivalent thereto should be construed as being included in the scope of the present disclosure.

1-9. (canceled)

10. A persistence of vision (POV) display device comprising:
a fixed module including a motor;
a rotatable module positioned on the fixed module and configured to be rotated by the motor;
a light source module comprising at least one panel coupled to the rotatable module;
a plurality of light sources arranged longitudinally on the at least one panel and comprising a plurality of pixels; and
a controller configured to generate at least one sub-frame between a first main frame and a second main frame for output by the panel,
wherein output of the first main frame temporally precedes the second main frame.

11. The POV display device of claim 10, wherein the controller is configured to:
multiply the first main frame and the second main frame by respective weights for each image scanning duration; and
generate the at least one sub-frame by combining the first main frame and the second main frame respectively multiplied by the weights.

12. The POV display device of claim 11, wherein:
linear weights are selected as the weights based on a difference between the first main frame and the second main frame being greater than or equal to a preset threshold value; and
non-linear weights are selected as the weights based on the difference being less than the preset threshold value.

13. The POV display device of claim 12, wherein based on the non-linear weights being selected as the weights, the controller is configured to increase the weights during a portion where the difference between the first main frame and the second main frame is less than a specific small threshold value

14. The POV display device of claim 11, wherein the panel includes a plurality of panels, and the controller is further configured to:
divide an image scanning area into respective areas corresponding to the plurality of panels; and
apply the weights respectively to the areas.

15. A method for controlling a persistence of vision (POV) display device, the method comprising:
inputting image data of a first main frame and a second main frame to be displayed;
detecting weights for each of the first main frame and the second main frame;
applying the weights respectively to the first main frame and the second main frame;
forming a sub-frame by combining the first main frame and the second main frame applied with the weights; and
outputting synthesized image data via the POV display device based on the first main frame, the second main frame, and the sub-frame.

16. The method of claim 15, wherein:
linear weights are selected as the weights based on a difference between the first main frame and the second main frame being greater than or equal to a preset threshold value; and
non-linear weights are selected as the weights based on the difference being less than the preset threshold value.

17. The method of claim 16, wherein selecting the non-linear weights as the weights includes:
pre-processing images of the first main frame and the second main frame; and
detecting the weights of the frames based on analysis of the images.

18. The method of claim 15, further comprising
dividing an image scanning area into respective areas corresponding to a plurality of panels before inputting of the image data of the first main frame and the second main frame.
